(19) United States
(12) Patent Application Publication
(10) Pub. No.: US 2014/0250352 A1
(43) Pub. Date: Sep. 4, 2014

(54) Systems and Methods for Signal Reduction Based Data Processor Marginalization

(71) Applicant: LSI CORPORATION, San Jose, CA (US)

(72) Inventors: Jun Xiao, Fremont, CA (US); Fan Zhang, Milpitas, CA (US); George Mathew, San Jose, CA (US)

(73) Assignee: LSI Corporation, San Jose, CA (US)

(21) Appl. No.: 13/784,369

(22) Filed: Mar. 4, 2013

(51) Int. Cl. H03M 13/39; H03H 17/06

(52) U.S. Cl. CPC H03M 13/3905; H03H 17/06
USPC 714/795; 708/300; 714/786

(57) ABSTRACT

Systems, methods, devices, circuits for data processing, and more particularly to data processing including operational marginalization capability, and/or operational improvement capability.

### FIELD OF THE INVENTION

Embodiments are related to systems and methods for data processing, and more particularly to systems and methods for controlled degradation of a data processing system.

### BACKGROUND

Various data transfer systems have been developed including storage systems, cellular telephone systems, radio transmission systems. In each of the systems data is transferred from a sender to a receiver via some medium. For example, in a storage system, data is sent from a sender (i.e., a write function) to a receiver (i.e., a read function) via a storage medium. The data processing includes application of various data processing algorithms to recover originally written data. Such processing results in a very small number of errors that in some cases are due to corruption of the originally received data. Such a level of errors make it difficult to make adjustments to either correct for the type of errors or make it difficult to characterize the quality of a device.

Hence, for at least the aforementioned reasons, there exists a need in the art for advanced systems and methods for data processing.

### SUMMARY

Embodiments are related to systems and methods for data processing, and more particularly to systems and methods for controlled degradation of a data processing system.

Various embodiments of the present invention provide data processing systems that include a signal modification circuit and a processing circuit. The signal modification circuit is operable to: filter a data set to yield a signal component; multiply the signal component by a scalar to yield a product; subtract the product from a data input to yield a signal modified output, wherein the data set is derived from the data input; and select one of the data set and the signal modified output as a processing input. The processing circuit is operable to apply a data processing algorithm to the processing input to yield a data output.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a storage system including signal reduction based data processor marginalization circuitry in accordance with various embodiments of the present invention;

FIG. 2 depicts a data transmission system including signal reduction based data processor marginalization circuitry in accordance with one or more embodiments of the present invention;

FIG. 3 shows a data processing circuit including a signal reduction based data processor marginalization circuit in accordance with some embodiments of the present invention;

FIGS. 4a-4b are flow diagrams showing a method for data processing relying on signal reduction based data processor marginalization in accordance with some embodiments of the present invention; and

FIG. 5 shows a subset of a data processing circuit including a resolution modified signal reduction based data processor marginalization circuit in accordance with some embodiments of the present invention.

### DETAILED DESCRIPTION OF SOME EMBODIMENTS

Embodiments are related to systems and methods for data processing, and more particularly to systems and methods for controlled degradation of a data processing system.

Various embodiments of the present invention provide data processing systems that include a signal modification circuit and a processing circuit. The signal modification circuit is operable to: filter a data set to yield a signal component; multiply the signal component by a scalar to yield a product; subtract the product from a data input to yield a signal modified output, wherein the data set is derived from the data input; and select one of the data set and the signal modified output as a processing input. The processing circuit is operable to apply a data processing algorithm to the processing input to yield a data output. In some cases, the system is implemented as an integrated circuit. In various cases, the data processing system is implemented as part of a storage device. In other cases, the data processing system is implemented as part of a communication device. Based upon the disclosure provided herein, one of ordinary skill in the art will recognize other types of devices in which the aforementioned systems may be implemented.

In some instances of the aforementioned embodiments, the scalar is programmable. In some such instances, the scalar is programmed with a value large enough to decrease a signal to noise ratio of the signal modified output when compared with a signal to noise ratio of the data set. In other such instances, the scalar is programmed with a value small enough to increase a reliability of the signal modified output when compared with the data set.

In various instances of the aforementioned embodiments, the data processing system further includes: an equalizer circuit operable to equalize a sample set to yield the data input; and a data detector circuit operable to apply a data detection algorithm to the data input to yield the data set. In some such instances, the resolution of the data input is greater than the resolution of the processing input. In some cases, the resolution of the data input is thirteen bits, and wherein the resolution of the processing input is six bits. In various of the aforementioned instances, the resolution of the signal component is greater than the resolution of the processing input. In one or more instances of the aforementioned embodiments, the signal modification circuit includes: a partial response target filter circuit operable to filter the data set to yield the signal component; a multiplier circuit operable to multiply the signal component by the scalar to yield the product; and summation circuit operable to subtract the product from the data input to yield the signal modified output.

Other embodiments of the present invention provide methods that include: receiving a data set; equalizing the data set to yield a data input; generating a signal component based at least in part on a second detected output derived from the data input; multiplying the signal component by a scalar to yield a product; subtracting the product from the data input to yield a signal modified output; selecting one of the data input and the signal modified output as a processing input; and applying a data detection algorithm to the processing input to yield a first detected output.

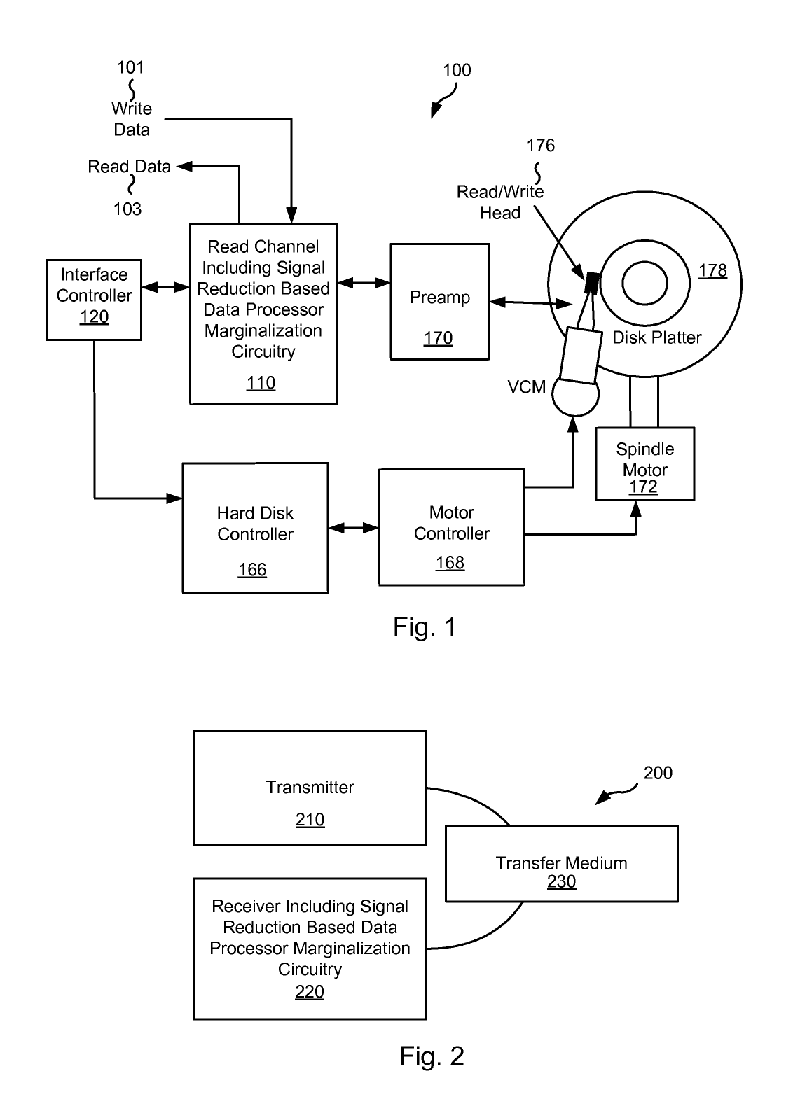

Turning to FIG. 1, a storage system 100 including a read channel circuit 110 having signal reduction based data processor marginalization circuitry is shown in accordance with various embodiments of the present invention. Storage system 100 may be, for example, a hard disk drive. Storage system 100 also includes a preamplifier 170, an interface controller 120, a hard disk controller 166, a motor controller 168, a spindle motor 172, a disk platter 178, and a read/write head 176. Interface controller 120 controls addressing and timing of data to/from disk platter 178. The data on disk platter 178 consists of groups of magnetic signals that may be detected by read/write head assembly 176 when the assembly is properly positioned over disk platter 178. In one embodiment, disk platter 178 includes magnetic signals recorded in accordance with either a longitudinal or a perpendicular recording scheme.

In a typical read operation, read/write head assembly 176 is accurately positioned by motor controller 168 over a desired data track on disk platter 178. Motor controller 168 both positions read/write head assembly 176 in relation to disk platter 178 and drives spindle motor 172 by moving read/write head assembly to the proper data track on disk platter 178 under the direction of hard disk controller 166. Spindle motor 172 spins disk platter 178 at a determined spin rate (RPMs). Once read/write head assembly 176 is positioned adjacent the proper data track, magnetic signals representing data on disk platter 178 are sensed by read/write head assembly 176 as disk platter 178 is rotated by spindle motor 172. The sensed magnetic signals are provided as a continuous, minute analog signal representative of the magnetic data on disk platter 178. This minute analog signal is transferred from read/write head assembly 176 to read channel circuit 110 via preamplifier 170. Preamplifier 170 is operable to amplify the minute analog signals accessed from disk platter 178. In turn, read channel circuit 110 decodes and digitizes the received analog signal to recreate the information originally written to disk platter 178. This data is provided as read data 103 to a receiving circuit. A write operation is substantially the opposite of the preceding read operation with write data 101 being provided to read channel circuit 110. This data is then encoded and written to disk platter 178.

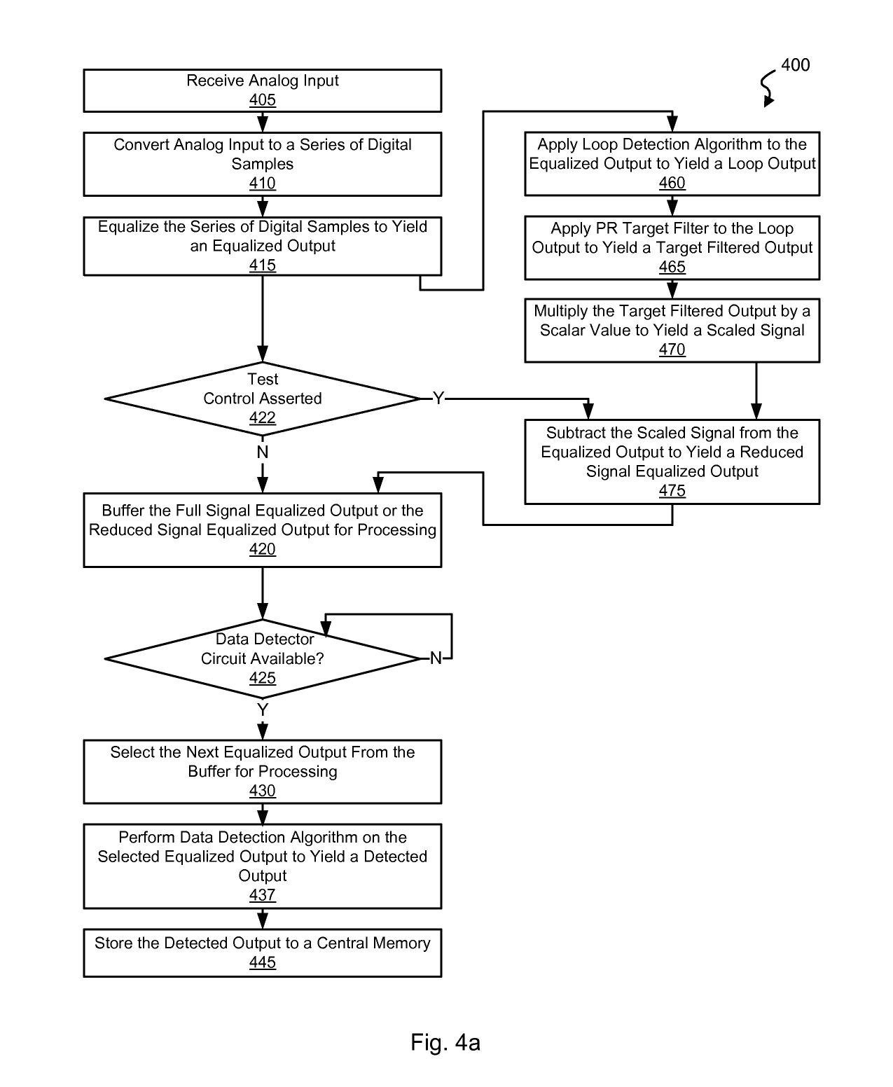

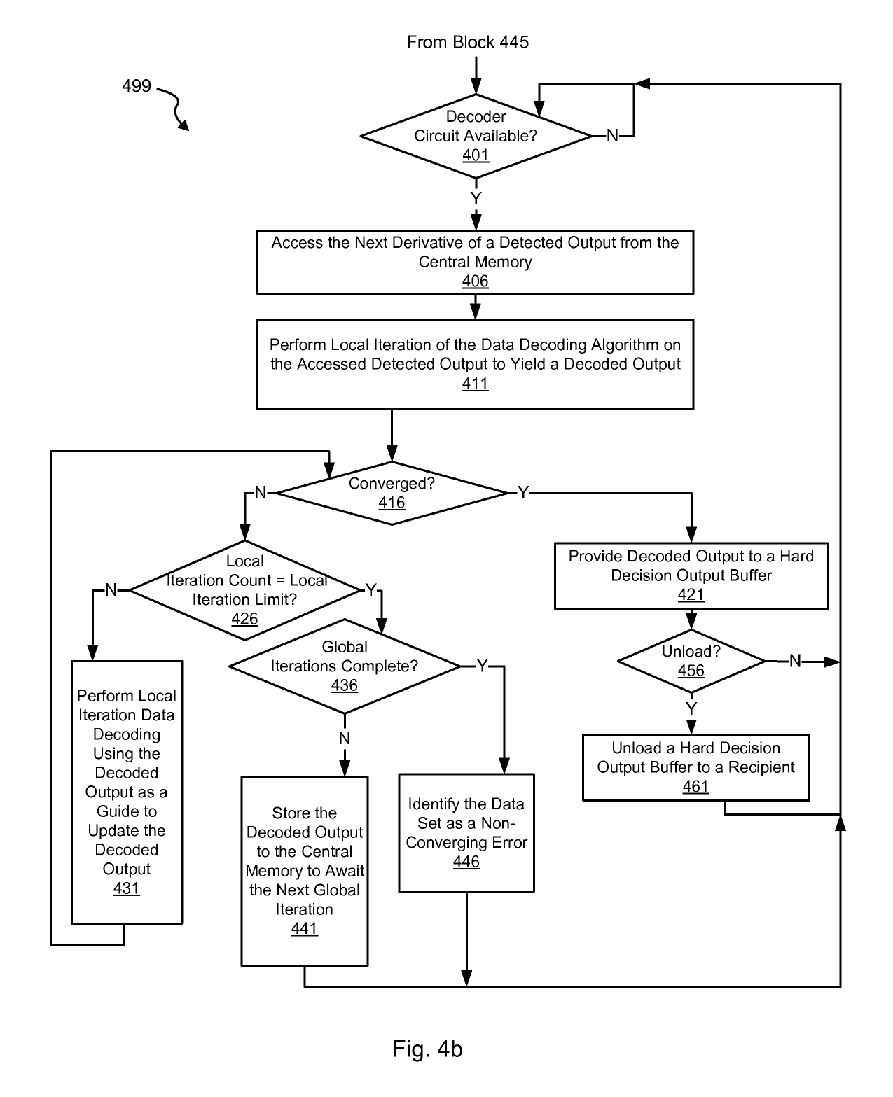

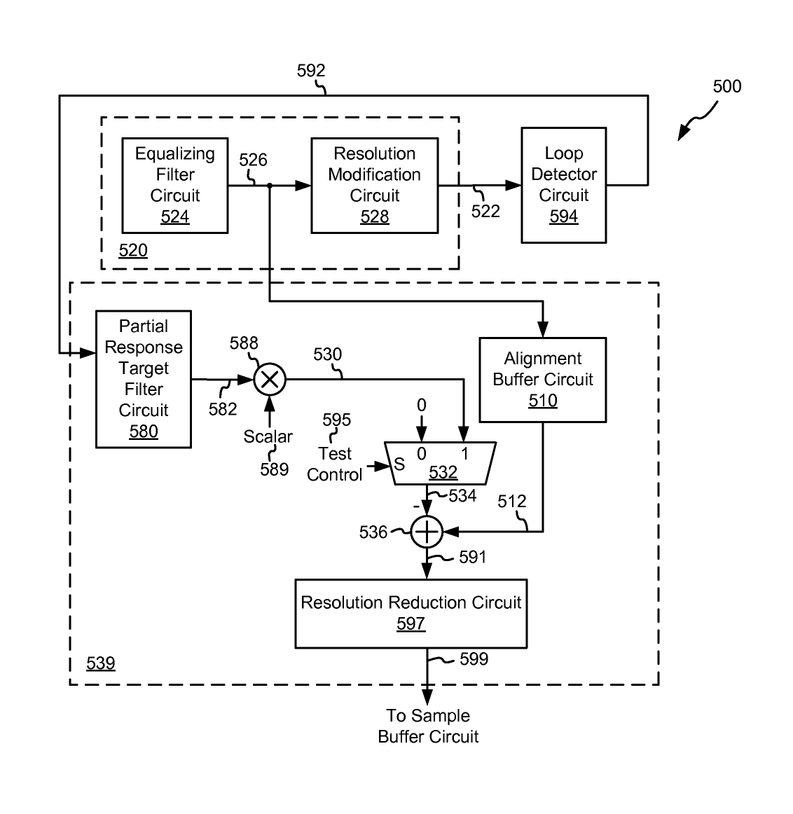

As part of a device characterization process, read channel circuit 110 selects a test control causing a signal component of an input derived from disk platter 178 to be scaled to yield a reduced signal component. The reduced signal component is then subtracted from the input while leaving the noise component of the input substantially unchanged. This subtraction results in a reduced signal input. In some cases, this reduced signal input exhibits a reliability higher than that exhibited by the original input. In some cases, the read channel circuit may include circuitry similar to that discussed in relation to FIG. 3 and/or FIG. 5 below; and/or may operate similar to the methods discussed below in relation to FIGS. 4a-4b.

It should be noted that storage system 100 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such as storage system 100, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

A data decoder circuit used in relation to read channel circuit 110 may be, but is not limited to, a low density parity check (LDPC) decoder circuit as are known in the art. Such low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

In addition, it should be noted that storage system 100 may be modified to include solid state memory that is used to store data in addition to the storage offered by disk platter 178. This solid state memory may be used in parallel to disk platter 178 to provide additional storage. In such a case, the solid state memory receives and provides information directly to read channel circuit 110. Alternatively, the solid state memory may be used as a cache where it offers faster access time than that offered by disk platted 178. In such a case, the solid state memory may be disposed between interface controller 120 and read channel circuit 110 where it operates as a pass through to disk platter 178 when requested data is not available in the solid state memory or when the solid state memory does not have sufficient storage to hold a newly written data set. Based upon the disclosure provided herein, one of ordinary skill in the art will recognize a variety of storage systems including both disk platter 178 and a solid state memory.

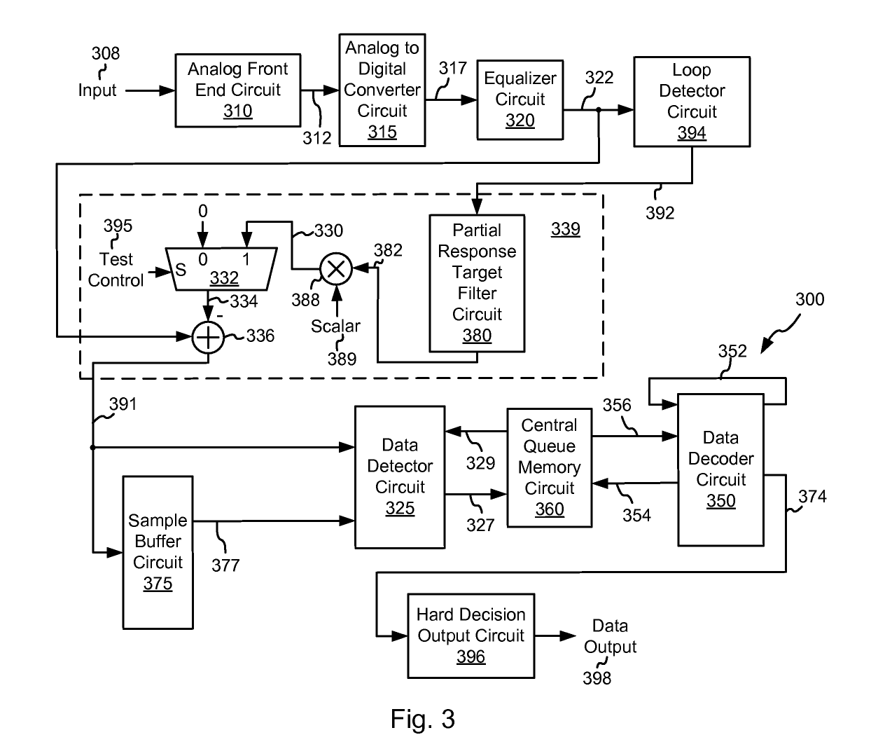

Turning to FIG. 2, a data transmission system 200 including a receiver 220 having including signal reduction based data processor marginalization circuitry is shown in accordance with various embodiments of the present invention. Data transmission system 200 includes a transmitter 210 that is operable to transmit encoded information via a transfer medium 230 as is known in the art. The noisy version of the encoded data is received from transfer medium 230 by a receiver 220. Receiver 220 processes the received input to yield the originally transmitted data.

As part of a device characterization process, receiver 220 selects a test control causing a signal component of an input derived from transfer medium 230 to be scaled to yield a reduced signal component. The reduced signal component is then subtracted from the input while leaving the noise component of the input substantially unchanged. This subtraction results in a reduced signal input. In some cases, this reduced signal input exhibits a reliability higher than that exhibited by the original input. In some cases, the receiver may include circuitry similar to that discussed in relation to FIG. 3 and/or FIG. 5 below; and/or may operate similar to the methods discussed below in relation to FIGS. 4a-4b.

FIG. 3 shows a data processing circuit 300 including a signal reduction based data processor marginalization circuit 339 in accordance with some embodiments of the present invention. Data processing circuit 300 includes an analog front end circuit 310 that receives an analog signal 308. Analog front end circuit 310 processes analog signal 308 and provides a processed analog signal 312 to an analog to digital converter circuit 315. Analog front end circuit 310 may include, but is not limited to, an analog filter and an amplifier circuit as are known in the art. Based upon the disclosure provided herein, one of ordinary skill in the art will recognize a variety of circuitry that may be included as part of analog front end circuit 310. In some cases, analog input signal 308 is derived from a read/write head assembly (not shown) that is disposed in relation to a storage medium (not shown). In other cases, analog input signal 308 is derived from a receiver circuit (not shown) that is operable to receive a signal from a transmission medium (not shown). The transmission medium may be wired or wireless. Based upon the disclosure provided herein, one of ordinary skill in the art will recognize a variety of source from which analog input signal 308 may be derived.

Analog to digital converter circuit 315 converts processed analog signal 312 into a corresponding series of digital samples 317. Analog to digital converter circuit 315 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 317 are provided to an equalizer circuit 320. Equalizer circuit 320 applies an equalization algorithm to digital samples 317 to yield an equalized output 322 (y[n]). In some embodiments of the present invention, equalizer circuit 320 is a digital finite impulse response filter circuit as are known in the art. It may be possible that equalized output 322 may be received directly from a storage device in, for example, a solid state storage system. In such cases, analog front end circuit 310, analog to digital converter circuit 315 and equalizer circuit 320 may be eliminated where the data is received as a digital data input.

Equalized output 322 is provided to signal reduction based data processor marginalization circuit 339 that operates to reduce a signal component of equalized output 322 while leaving a noise component of equalized output substantially unchanged. As shown later, in some cases for small values of the scalar, this signal reduction based data processor marginalization circuit 339 increases the reliability in a signal reduced output 391 when compared to equalized output 322. Signal reduction based data processor marginalization circuit 339 includes a partial response target filter circuit 380, a multiplier circuit 388, a selector circuit 332, and a summation circuit 336. In operation, partial response target filter circuit 380 receives a detected output 392 (â[n]) from a loop detector circuit 394 that is more fully described below. Detected output 392 is a representation, and is derived from, the data from which analog signal 308 was derived. Partial response target filter circuit 380 may be any circuit known in the art that is capable of applying target based filtering to an input signal to yield an output conformed to a target. In this case, partial response target filter circuit 380 applies target filtering to detected output 392 to yield a target filtered output 382. Target filtered output 382 is an ideal approximation of equalized output 322. Said another way, target filtered output 382 represents a signal component of equalized output 322.

Target filtered output 382 is provided to multiplier circuit 388 where it is multiplied by a scalar 389 to yield a product 330. In some cases, scalar 389 is programmable, while in other cases it is fixed. In one particular embodiment, scalar 389 is less than unity (i.e., ‘1’), in which case, product 330 represents a reduced signal value. Product 330 is provided to selector circuit 332. When a test control 395 is asserted to indicate that test data is selected, product 330 is provided by selector circuit 332 as a signal reduction component 334 (q[n]). Otherwise, when test control 395 is asserted to indicate standard processing, a zero value ‘0’ is provided by selector circuit 332 as signal reduction component 334. Test control 395 may be user programmable. Test control 395 may be asserted to indicate that test data is selected when a user desires to test operation of data processing circuit 300. Test control 395 may be de-asserted to indicate that standard data is selected when a user desires standard operation of data processing circuit 300. Signal reduction component 334 is provided to summation circuit 336 where it is subtracted from equalized output 322 to yield signal reduced output 391. Where standard operation of data processing circuit 300 is selected by test control 395, signal reduced output 391 is equalized output 322 unmodified.

The attenuation of signal in signal reduced output 391 (z[n]) may be represented by the following equation:

$$z [ n ] = y [ n ] - q [ n ] , where$$

$$q [ n ] = α {\sum }_{k} \hat{a} [ n - k ] g [ k ] and y [ n ] = {\sum }_{k} a [ n - k ] g [ k ] + e [ n ] .$$

In the aforementioned equations, g[k] is the partial response target used by partial response target filter 380, a[n] is the true NRZ decisions (i.e., signal component of equalized output 322), and e[n] is a noise component of equalized output 322. The aforementioned equation may be re-written as:

$$z [ n ] = {\sum }_{k} a [ n - k ] g [ k ] + e [ n ] - α {\sum }_{k} \hat{a} [ n - k ] g [ k ] , or$$

$$z [ n ] = e [ n ] + {\sum }_{k} [ ( a [ n - k ] ) - α ( \hat{a} [ n - k ] ) ] g [ k ] .$$

The following portion of the above mentioned equation represents the attenuated signal:

$$s [ n ] = {\sum }_{k} [ ( a [ n - k ] ) - α ( \hat{a} [ n - k ] ) ] g [ k ] ,$$

and e[n] represents the noise. As e[n] is not attenuated and the signal is attenuated, the signal to noise ratio of z[n] is decreased.

Careful consideration of the aforementioned equations reveal a use of data processing system 300 in addition to the previously described signal attenuation. In particular, where a very small value is used for scalar 389 (i.e., a small value of α), then performance of data processing system 300 may be improved. Detected output 392 (â[n]) may be statistically described by the following equation:

$$\hat{a} [ n ] = \{ \begin{matrix}a [ n ] , & with probability of ( 1 - BER ) \\ - a [ n ] , & with probability of ( BER ) ,\end{matrix}$$

where BER stands for the bit error rate in detected output 392. As such, the signal portion s[n] in signal reduced output 391 may be statistically described by the following equation:

$$s [ n ] = \{ \begin{matrix}+ 1 - α , & with probability of ( 0.5 ( 1 - BER ) \\ + 1 + α , & with probability of ( BER / 2 ) \\ - 1 - α , & with probability of ( BER / 2 ) \\ - 1 + α , & 0.5 ( 1 - BER )\end{matrix}$$

Following the aforementioned statistical representation of the signal component, additional signal is added in the situation where detected output 392 is not correct (+1+α, BER/2 and −1−α, BER/2), and signal is subtracted in the situations where detected output 392 is correct (i.e., +1+α, 0.5(1−BER) and −1+α, 0.5(1−BER)). Assuming that correct decisions as more likely to exhibit higher margins of error than incorrect decisions, the use of a small value for scalar 389 (α) will have a disproportionate impact on incorrect decisions. Said another way, where a small value for scalar 389 is used, it is more likely that incorrect decisions will be changed to correct decisions than for correct decisions to be changed to incorrect decisions. As such, use of a small value for scalar 389 has an ability to improve performance of data processing system 300 in contrast to use of higher values for scalar 389 that marginalize performance as described above.

Equalized output 322 is also provided to loop detector circuit 394. Loop detector circuit 394 may be any circuit known in the art that applies some type of algorithm designed to return a representation of the data from which analog signal 308 was derived. In one particular embodiment of the present invention, loop detector circuit 394 is operable to determine timing feedback and other operations designed to align the sampling of analog to digital converter circuit 315 with the received data set, and/or to adjust a gain applied by analog front end circuit 310. Based upon the disclosure provided herein, one of ordinary skill in the art will recognize a variety of circuits capable of providing a representation of the data from which analog signal 308 was derived that may be used in relation to different embodiments of the present invention.

In addition, signal reduced output 391 is stored to a sample buffer circuit 375 that includes sufficient memory to maintain one or more codewords until processing of that codeword is completed through data detector circuit 325 and a data decoder circuit 350 including, where warranted, multiple “global iterations” defined as passes through both data detector circuit 325 and data decoder circuit 350 and/or “local iterations” defined as passes through data decoding circuit 350 during a given global iteration. Sample buffer circuit 375 stores the received data as buffered data 377.

Data detector circuit 325 is a data detector circuit capable of producing a detected output 327 by applying a data detection algorithm to a data input. As some examples, the data detection algorithm may be but is not limited to, a Viterbi algorithm detection algorithm or a maximum a posteriori detection algorithm as are known in the art. Based upon the disclosure provided herein, one of ordinary skill in the art will recognize a variety of data detection algorithms that may be used in relation to different embodiments of the present invention. Data detector circuit 325 may provide both hard decisions and soft decisions. The terms “hard decisions” and “soft decisions” are used in their broadest sense. In particular, “hard decisions” are outputs indicating an expected original input value (e.g., a binary ‘1’ or ‘0’, or a non-binary digital value), and the “soft decisions” indicate a likelihood that corresponding hard decisions are correct. Based upon the disclosure provided herein, one of ordinary skill in the art will recognize a variety of hard decisions and soft decisions that may be used in relation to different embodiments of the present invention.

Detected output 327 is provided to a central queue memory circuit 360 that operates to buffer data passed between data detector circuit 325 and data decoder circuit 350. When data decoder circuit 350 is available, data decoder circuit 350 receives detected output 327 from central queue memory 360 as a decoder input 356. Data decoder circuit 350 applies a data decoding algorithm to decoder input 356 in an attempt to recover originally written data. The result of the data decoding algorithm is provided as a decoded output 354. Similar to detected output 327, decoded output 354 may include both hard decisions and soft decisions. For example, data decoder circuit 350 may be any data decoder circuit known in the art that is capable of applying a decoding algorithm to a received input. Data decoder circuit 350 may be, but is not limited to, a low density parity check decoder circuit or a Reed Solomon decoder circuit as are known in the art. Based upon the disclosure provided herein, one of ordinary skill in the art will recognize a variety of data decoder circuits that may be used in relation to different embodiments of the present invention. Where the original data is recovered (i.e., the data decoding algorithm converges) or a timeout condition occurs, data decoder circuit 350 provides the result of the data decoding algorithm as a data output 374. Data output 374 is provided to a hard decision output circuit 396 where the data is reordered before providing a series of ordered data sets as a data output 398.

One or more iterations through the combination of data detector circuit 325 and data decoder circuit 350 may be made in an effort to converge on the originally written data set. As mentioned above, processing through both the data detector circuit and the data decoder circuit is referred to as a “global iteration”. For the first global iteration, data detector circuit 325 applies the data detection algorithm without guidance from a decoded output. For subsequent global iterations, data detector circuit 325 applies the data detection algorithm to buffered data 377 as guided by decoded output 354. Decoded output 354 is received from central queue memory 360 as a detector input 329.

During each global iteration it is possible for data decoder circuit 350 to make one or more local iterations including application of the data decoding algorithm to decoder input 356. For the first local iteration, data decoder circuit 350 applies the data decoder algorithm without guidance from a decoded output 352. For subsequent local iterations, data decoder circuit 350 applies the data decoding algorithm to decoder input 356 as guided by a previous decoded output 352. In some embodiments of the present invention, a default of ten local iterations is allowed for each global iteration.

Turning to FIGS. 4a-4b are flow diagrams 400, 499 showing a method for data processing relying on signal reduction based data processor marginalization in accordance with some embodiments of the present invention. Following flow diagram 400 of FIG. 4a, an analog input is received (block 405). The analog input may be derived from, for example, a storage medium or a data transmission channel. Based upon the disclosure provided herein, one of ordinary skill in the art will recognize a variety of sources of the analog input. The analog input is converted to a series of digital samples (block 410). This conversion may be done using an analog to digital converter circuit or system as are known in the art. Of note, any circuit known in the art that is capable of converting an analog signal into a series of digital values representing the received analog signal may be used. The resulting digital samples are equalized to yield an equalized output (block 415). In some embodiments of the present invention, the equalization is done using a digital finite impulse response circuit as are known in the art. Based upon the disclosure provided herein, one of ordinary skill in the art will recognize a variety of equalizer circuits that may be used in place of such a digital finite impulse response circuit to perform equalization in accordance with different embodiments of the present invention.

A loop detection algorithm is applied to the equalized output to yield a loop output (block 460). The loop detection algorithm may be applied by any circuit known in the art that applies some type of algorithm designed to return a representation of the data from which the analog input was derived. In one particular embodiment of the present invention, the loop detection algorithm is operable to determine timing feedback and other operations designed to align the sampling related to the analog to digital conversion, and/or to adjust a gain applied by an analog front end circuit. Based upon the disclosure provided herein, one of ordinary skill in the art will recognize a variety of loop detection algorithms capable of providing a representation of the data from which the analog input was derived that may be used in relation to different embodiments of the present invention.

A partial response target filtering is applied to the loop output to yield a target filtered output (block 465). The partial response target filtering may be done by any circuit known in the art that is capable of applying target based filtering to an input signal to yield an output conformed to a target. The resulting target filtered output is an ideal approximation of the equalized output. The target filtered output is then multiplied by a scalar value to yield a scaled signal (block 470). In some cases, the scalar value is programmable, while in other cases it is fixed. In one particular embodiment, the scalar value is less than unity (i.e., ‘1’), in which case, the scaled signal represents a reduced signal value.

It is determined whether a test control is asserted indicating that signal reduced test data has been selected (block 422). Where the test control is not asserted (block 422), the equalized output including the full signal (i.e., the signal component of the equalized output is not attenuated) is buffered (block 420). Alternatively, where the test control is asserted (block 422), the scaled signal is subtracted from the equalized output to yield a reduced signal equalized output (block 475), and the reduced signal equalized output is buffered (block 420).

It is determined whether a data detector circuit is available to process the buffered equalized output (block 425). Where a data detector circuit is available to process a data set (block 425), the next available equalized output from the buffer is selected for processing (block 430). A data detection algorithm is then applied to the selected equalized output to yield a detected output (block 437). The data detection algorithm may be, for example, a Viterbi algorithm data detection or a maximum a posteriori data detection algorithm. The detected output (or a derivative thereof) is then stored to a central memory (block 445).

Turning to FIG. 4b and following flow diagram 499, it is determined whether a data decoder circuit is available (block 401) in parallel to the previously described data detection process of FIG. 4a. The data decoder circuit may be, for example, a low density parity check data decoder circuit as are known in the art. Where the data decoder circuit is available (block 401) the next derivative of a detected output is selected from the central memory (block 406). The derivative of the detected output may be, for example, an interleaved (shuffled) version of a detected output from the data detector circuit. A first local iteration of a data decoding algorithm is applied by the data decoder circuit to the selected detected output to yield a decoded output (block 411). It is then determined whether the decoded output converged (e.g., resulted in the originally written data as indicated by the lack of remaining unsatisfied checks) (block 416).

Where the decoded output converged (block 416), it is provided as a decoded output codeword to a hard decision output buffer (e.g., a re-ordering buffer) (block 421). It is determined whether the received output codeword is either sequential to a previously reported output codeword in which case reporting the currently received output codeword immediately would be in order, or that the currently received output codeword completes an ordered set of a number of codewords in which case reporting the completed, ordered set of codewords would be in order (block 456). Where the currently received output codeword is either sequential to a previously reported codeword or completes an ordered set of codewords (block 456), the currently received output codeword and, where applicable, other codewords forming an in order sequence of codewords are provided to a recipient as an output (block 461).

Alternatively, where the decoded output failed to converge (e.g., errors remain) (block 416), it is determined whether the number of local iterations already applied equals the maximum number of local iterations (block 426). In some cases, a default seven local iterations are allowed per each global iteration. Based upon the disclosure provided herein, one of ordinary skill in the art will recognize another default number of local iterations that may be used in relation to different embodiments of the present invention. Where another local iteration is allowed (block 426), the data decoding algorithm is applied to the selected data set using the decoded output as a guide to update the decoded output (block 431). The processes of blocks starting at block 416 are repeated for the next local iteration.

Alternatively, where all of the local iterations have occurred (block 426), it is determined whether all of the global iterations have been applied to the currently processing data set (block 436). Where the number of global iterations has not completed (block 436), the decoded output is stored to the central queue memory circuit to await the next global iteration (block 441). Alternatively, where the number of global iterations has completed (block 436), an error is indicated and the data set is identified as non-converging (block 446).

FIG. 5 shows a subset of a data processing circuit 500 including a including a resolution modified signal reduction based data processor marginalization circuit 539 in accordance with some embodiments of the present invention. Data processing circuit 500 is similar to data processing circuit 300 described above in relation to FIG. 3, except that data processing circuit 500 further includes resolution modification circuitry used to enhance the accuracy of operational marginalization. In particular, an equalizer circuit 520 may be used in place of equalizer circuit 320 of FIG. 3, resolution modified sample based noise injection circuit 539 may be used in place of sample based noise injection circuit 339 of FIG. 3, and loop detector circuit 594 may be used in place of loop detector circuit 394. As with data processing circuit 300, equalizer circuit 520 receives a data input that may be derived, for example, from a storage medium. Equalizer circuit 520 includes an equalizing filter circuit 524 and a resolution modification circuit 528. Equalizing filter circuit 524 applies an equalization algorithm to a received data set to yield an equalized output 526. In particular embodiments of the present invention, equalized output 526 is a thirteen bit resolution. In some embodiments of the present invention, equalizing filter circuit 524 is a digital finite impulse response filter circuit as are known in the art.

Equalized output 526 is provided to a resolution modification circuit 528. Resolution modification circuit 528 reduces the resolution of equalized output 526 to yield a reduced resolution equalized output 522. In some embodiments of the present invention, reduced resolution equalized output 522 has six bits of resolution. In some cases, resolution modification circuit 528 truncates the value of equalized output 526 to match the resolution of reduced resolution equalized output 522.

In addition, equalized output 526 is provided to an alignment buffer circuit 510 that is operable to delay equalized output 526 to provide a delayed output 512 that is aligned with a detected output derived from the corresponding instances of equalized output 526. Delayed output 512 is provided to a summation circuit 536 where a signal reduction component 534 is subtracted there from to yield a signal reduced output 591. Signal reduced output 591 is provided to a resolution reduction circuit 597 that reduces the resolution of signal reduced output 591 to yield a marginalized output 599. The resolution reduction operates to match the resolution of marginalized output 599 to the input resolution of a downstream data processing circuit (e.g., the processing circuit including data detector circuit 325 shown in FIG. 3) fed by a sample buffer circuit (e.g., sample buffer circuit 375 of FIG. 3). In some embodiments of the present invention, marginalized output 599 exhibits six bits of resolution. In some cases, resolution reduction circuit 597 truncates the value of signal reduced output 591 to match the resolution supported by the downstream data processing circuit.

Resolution modified signal reduction based data processor marginalization circuit 539 includes a partial response target filter circuit 580, a multiplier circuit 588, a selector circuit 532, and summation circuit 536. In operation, partial response target filter circuit 580 receives a detected output 592 from a loop detector circuit 594 that is more fully described below. Detected output 592 is a representation, and is derived from, the data from which equalized output 526 is derived. In one embodiment of the present invention, equalized output 522 (i.e., the input of the data detector circuit) may be a six bit resolution output. Partial response target filter circuit 580 may be any circuit known in the art that is capable of applying target based filtering to an input signal to yield an output conformed to a target. In this case, partial response target filter circuit 580 applies target filtering to detected output 592 to yield a target filtered output 582. Target filtered output 582 is an ideal approximation of equalized output 526.

Target filtered output 582 is provided to multiplier circuit 588 where it is multiplied by a scalar 589 to yield a product 530. In some cases, scalar 589 is programmable, while in other cases it is fixed. In one particular embodiment, scalar 589 is less than unity (i.e., ‘1’), in which case, product 530 represents a reduced signal value. Product 530 is provided to selector circuit 532. When a test control 595 is asserted to indicate that test data is selected, product 530 is provided by selector circuit 532 as a signal reduction component 534. Otherwise, when test control 595 is asserted to indicate standard processing, a zero value ‘0’ is provided by selector circuit 532 as signal reduction component 534. Test control 595 may be user programmable. Test control 595 may be asserted to indicate that test data is selected when a user desires to test operation of data processing circuit 500. Test control 595 may be de-asserted to indicate that standard data is selected when a user desires standard operation of data processing circuit 500. Signal reduction component 534 is provided to summation circuit 536 where it is subtracted from equalized output 522 to yield signal reduced output 591. Where standard operation of data processing circuit 500 is selected by test control 595, signal reduced output 591 is equalized output 522 unmodified.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the invention provides novel systems, devices, methods and arrangements for out of order data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A data processing system, the data processing system comprising:
a signal modification circuit operable to:
filter a data set to yield a signal component;
multiply the signal component by a scalar to yield a product;
subtract the product from a data input to yield a signal modified output, wherein the data set is derived from the data input; and
select one of the data set and the signal modified output as a processing input; and
a processing circuit operable to apply a data processing algorithm to the processing input to yield a data output.

2. The data processing system of claim 1, wherein the scalar is programmable.

3. The data processing system of claim 2, wherein the scalar is programmed with a value less than unity that is large enough to decrease a signal to noise ratio of the signal modified output when compared with a signal to noise ratio of the data set.

4. The data processing system of claim 2, wherein the scalar is programmed with a value less than unity that is small enough to increase a reliability of the signal modified output when compared with the data set.

5. The data processing system of claim 1, wherein the data processing system further comprises:
an equalizer circuit operable to equalize a sample set to yield the data input; and
a data detector circuit operable to apply a data detection algorithm to the data input to yield the data set.

6. The data processing system of claim 5, wherein the resolution of the data input is greater than the resolution of the processing input.

7. The data processing system of claim 6, wherein the resolution of the data input is thirteen bits, and wherein the resolution of the processing input is six bits.

8. The data processing system of claim 5, wherein the resolution of the signal component is greater than the resolution of the processing input.

9. The data processing system of claim 1, wherein the signal modification circuit comprises:
a partial response target filter circuit operable to filter the data set to yield the signal component;
a multiplier circuit operable to multiply the signal component by the scalar to yield the product; and
summation circuit operable to subtract the product from the data input to yield the signal modified output.

10. The data processing system of claim 1, wherein the scalar is less than unity.

11. The data processing system of claim 1, wherein the processing circuit comprises:
a data detector circuit operable to apply a data detection algorithm to the processing input to yield a detected output; and
a data decoder circuit operable to apply a data decoding algorithm to a decoder input derived from the detected output to yield the data output.

12. The data processing system of claim 11, wherein the data decoder circuit is a low density parity check decoder circuit.

13. The data processing system of claim 11, wherein the data detector circuit is selected from a group consisting of: a maximum a posteriori data detector circuit, and a Viterbi algorithm data detector circuit.

14. The data processing system of claim 1, wherein the system is implemented as an integrated circuit.

15. The data processing system of claim 1, wherein the data processing system is implemented as part of a device selected from a group consisting of: a storage device, and a communication device.

16. A method for data processing, the method comprising:
receiving a data set;
equalizing the data set to yield a data input;
generating a signal component based at least in part on a second detected output derived from the data input;
multiplying the signal component by a scalar to yield a product;
subtracting the product from the data input to yield a signal modified output;
selecting one of the data input and the signal modified output as a processing input;
applying a data detection algorithm to the processing input to yield a first detected output.

17. The method of claim 16, wherein the scalar is programmable, and wherein the method further comprises:
programming the scalar with a value less than unity that is large enough to decrease a signal to noise ratio of the signal modified output when compared with a signal to noise ratio of the data input.

18. The method of claim 16, wherein the scalar is programmable, and wherein the method further comprises:
programming the scalar with a value less than unity that is small enough to increase a reliability of the signal modified output when compared with the data set.

19. The method of claim 16, wherein the data detection algorithm is a first data detection algorithm, and wherein the method further comprises:
applying a second data detection algorithm to the data input to yield the second detected output.

20. A storage device, the storage device comprising:
a storage medium;
a head assembly disposed in relation to the storage medium and operable to provide a sensed signal corresponding to a data set on the storage;
a read channel circuit including:
an analog front end circuit operable to provide an analog signal corresponding to the sensed signal;
an analog to digital converter circuit operable to sample the analog signal to yield a series of digital samples;
an equalizer circuit operable to equalize the digital samples corresponding to the data set to yield a data set;
a loop detector circuit operable to apply a loop detection algorithm to the data set to yield a detected output;
a signal modification circuit operable to:
filter the detected output to yield a signal component;
multiply the signal component by a scalar to yield a product;
subtract the product from a data set to yield a signal modified output, wherein the data set is derived from the data input;
select one of the data set and the signal modified output as a processing input; and
a processing circuit operable to apply a data processing algorithm to the processing input to yield a data output.
